(19) United States
(12) Patent Application Publication
(10) Pub. No.: US 2024/0047941 A1
(43) Pub. Date: Feb. 8, 2024

(54) Wavelength Tunable Optical Transmitter

(71) Applicant: Nippon Telegraph and Telephone Corporation, Tokyo (JP)

(72) Inventors: Takahiko Shindo, Musashino-shi, Tokyo (JP); Meishin Chin, Musashino-shi, Tokyo (JP); Shigeru Kanazawa, Musashino-shi, Tokyo (JP)

(21) Appl. No.: 18/256,098

(22) PCT Filed: Dec. 10, 2020
(86) PCT No.: PCT/JP2020/046022

§ 371 Date: Jun. 6, 2023

(51) Int. Cl. H01S 5/06; H01S 5/125

(52) U.S. Cl. CPC H01S 5/0611; H01S 5/125

(57) ABSTRACT

In a DBR laser of a wavelength-tunable transmitter, a rear DBR region, an active region, and a front DBR region are integrated along an optical axis direction. The diffraction grating structure is set so that an oscillation mode using a reflection peak on the shortest wavelength side among a plurality of reflection peaks corresponding to the wavelength-tunable band is easily oscillated the most in a state where a current to the two DBR regions of the SSG-BPFR is 0. The SSG-DBR laser is configured such that the average period value of the diffraction grating of the front DBR is larger than the average period value of the diffraction grating of the rear DBR. The diffraction grating is configured so that the wavelengths of the reflection peaks on the shortest wavelength side among the plurality of reflection peaks coincide with each other between the two DBR regions in a state where no current is supplied.

### TECHNICAL FIELD

The present invention relates to an optical transmitter. More particularly, the present invention relates to a wavelength-tunable optical transmitter in which an optical modulator and a wavelength-tunable light source are integrated.

### BACKGROUND ART

Network traffic has increased explosively with the recent spread of video distribution services and increased demand for mobile traffic. In an optical communication system, a wavelength division multiplexing (WDM) system for transmitting a plurality of wavelengths through the same optical fiber is becoming increasingly important. In addition to various characteristics such as high-speed modulation and high optical output, the demand for devices with wavelength tunability in a single element has been growing in semiconductor modulation light sources for next-generation networks.

Distributed feedback (DFB) lasers with integrated electro-absorption (EA) modulators (EA modulators) (referred to as EADFB lasers hereinafter) have been used in a wide range of applications because of their higher extinction characteristics and superior chirp characteristics compared to directly modulated lasers.

FIG. 1 is a diagram showing a schematic configuration of a general EADFB laser. An integrated EADFB laser 100 has a structure in which a DFB laser 10 and an EA modulator 20 are integrated on the same chip. The DFB laser 10 includes an active layer 1 composed of a multiple quantum well (MQW), and oscillates at a single wavelength by a diffraction grating 3 formed in a resonator. The EA modulator includes a light absorption layer 2 composed of a MQW having a composition different from that of the DFB laser, and changes the light absorption amount of the light absorption layer 2 by voltage control performed by a modulation signal source 12. The EA modulator is driven under conditions where the output light from the DFB laser 10 is transmitted or absorbed, causing the light to flicker and converting the electrical signal into a modulated optical signal 4. Since the EADFB laser 100 performs modulation by utilizing the light absorption of the EA modulator, there is a trade-off relationship between a sufficient extinction characteristic and a high optical output.

FIG. 2 is a diagram schematically showing an extinction curve of an EADFB laser and the intensity modulation principle. The horizontal axis represents the reverse voltage applied to the EA modulator, and the vertical axis represents the extinction ratio. In a general EADFB laser, one technique for increasing the output is to reduce the absolute value of the reverse voltage applied to the EA modulator and to suppress light absorption in the EA modulator. In FIG. 2, both Vdc and Vpp may be reduced. However, in this case, the steepness of the extinction curve of the EA modulator is reduced, and the dynamic extinction ratio (DER) is deteriorated.

Another technique is to increase the drive current of the DFB laser to increase the intensity of light incident on the EA modulator from the DFB laser. In this case as well, the power consumption of the DFB laser increases and the extinction characteristics deteriorate due to light absorption in the EA modulator and the associated increase in photocurrent. Further, the power consumption of the entire chip increases. Thus, in order to achieve both sufficient optical output and modulation characteristics (dynamic extinction ratio) in the EADFB laser, an increase in power consumption was inevitable. To solve this problem, there has been proposed an EADFB laser (SOA Assisted Extended Reach EADFB Laser: AXEL), in which a semiconductor optical amplifier (SOA) is further integrated at the light emitting end of the EADFB laser (NPL 1).

FIG. 3 is a diagram showing a schematic configuration of an AXEL in which an SOA is integrated in an EADFB laser. In an AXL 200, signal light modulated by the EA modulator 20 is amplified by an integrated SOA region 30, to obtain signal light 4. The optical output can be increased without deteriorating the quality of the optical signal waveform. As compared with the EADFB laser shown in FIG. 1, the output can be increased without excessively increasing the driving current of the DFB laser 10 and the photocurrent of the EA modulator 20. Furthermore, in the AXEL 200, the same MQW structure as an active layer 1a of the DFB laser is used for an active layer 1b of the SOA. A device can be fabricated in the same manufacturing process as the EADFB laser 100 without adding a new regrowth process for the integration of the SOA region 30.

In AXEL, a device in which the DFB laser region is replaced with a distributed Bragg reflector (DBR) laser has also been reported (PTL 1). The DBR laser forms a resonator by using two DBR regions before and after an active region, and operates in a single mode. Compared to the DFB laser, the DBR laser has higher resistance to reflected return light, and laser oscillation is less likely to become unstable even in the presence of returned light. In addition, since the oscillation wavelength can be changed by applying a current to the DBR region, the DBR laser can also be used as a wavelength-tunable laser.

FIG. 4 is a diagram schematically showing a cross-sectional structure of a general DBR laser. A wavelength-tunable DBR laser 300 includes an active region 50 generating an optical gain by current injection, a rear DBR region 40a consisting of a waveguide 5a having diffraction gratings 6a at both ends along the optical axis direction of the active region, and a front DBR region 40b consisting of a waveguide 5b having a diffraction grating 6b. Anti-reflection (AR) films 7a and 7b are configured on the substrate end surfaces of the rear DBR region 40a and the front DBR region 40b.

FIG. 5 is a diagram for explaining control of reflection spectra and oscillation wavelengths of the two DBR regions of the DBR laser. FIG. 5(a) shows the reflective index of the two DBR regions. The diffraction gratings 6a and 6b are designed so as to have a peak of reflective index at the same Bragg wavelength λ_{Bragg} with respect to a reflective index 51 of the rear DBR region and a reflective index 52 of the front DBR region. As shown in the spectra in FIG. 5(a), the DBRs act as a mirror that selectively reflects a specific wavelength range around the Bragg wavelength λ_{Bragg}, which is determined by the period (pitch and length of the repeating structure) of the diffraction gratings. The Bragg wavelength λ_{Bragg} is determined by a diffraction grating period, and the same Bragg wavelength is obtained by normally providing the same period of diffraction gratings of the two DBR regions 40a and 40b. Therefore, only the wavelengths in the two DBR reflection bands are selectively confined in the resonator, and an amplification effect is obtained in the active region 50, resulting in oscillation.

When the wavelength band confined in the resonator by the two DBR regions 40a and 40b is sufficiently narrow, the DBR laser oscillates in a single mode. Further, by adjusting the reflective index of the DBR regions 40a and 40b, the optical output from the front end face and the rear end face can be adjusted. That is, by designing the reflective index of the front DBR region 40b to be smaller than that of the rear DBR region 40a, the optical output from the rear end face can be suppressed and the optical output from the front end face can be increased. Although the diffraction gratings of the two DBR regions are generally formed in the same structure, the reflective index of the DBR regions can be adjusted by the lengths of the DBR regions.

The Bragg wavelengths of the DBR regions are expressed by the following equation.

λ_{Bragg}=2n_{eg}Λ Equation(1)

Here, Λ represents the diffraction grating period, and n_{eq} represents the equivalent refractive index.

When the oscillation wavelength of the DBR laser is changed, the equivalent refractive index n_{eq} of the DBR region is changed by some sort of method. In order to change the oscillation wavelength while maintaining the oscillation state of the DBR laser, the Bragg wavelengths of the both two regions are adjusted to be simultaneously changed while keeping the Bragg wavelengths of the both DBR regions coincide with each other.

FIG. 5(b) is a schematic diagram for explaining the control of the oscillation wavelengths by changing the Bragg wavelengths. Generally, as a technique for changing the refractive index, a technique for temperature adjustment or a technique for using a carrier plasma effect generated by injecting a current into a DBR region is used. The carrier plasma effect is a phenomenon in which the carrier density in a DBR region is increased by current injection and the refractive index is lowered. Referring to the equation (1) showing the Bragg wavelengths, the equivalent refractive index n_{eq} decreases, and thereby the Bragg wavelengths shift to the short wavelength side. As shown in FIG. 5(b), the oscillation wavelength can be changed while maintaining the oscillation state by injecting a current 13 to the rear DBR region 40a and a current 14 to the front DBR region 40b in a state where the Bragg wavelengths of the two DBR coincide with each other.

As a wavelength-tunable laser using the carrier plasma effect, InGaAsP/InP-based material is used. A large number of DBR lasers with a 5 μm band have been reported (NPL 2). Also, wavelength-tunable DBR lasers that employ special grating structures such as sampled gratings (SG) and superstructure gratings (SSG) have also been reported, which significantly broaden a wavelength-tunable bandwidth. Furthermore, a wavelength-tunable modulation light source in which an EA modulator and a DBR laser are integrated has been reported (NPL 4). An SSG-DBR laser having a plurality of reflection peaks and capable of widening a wavelength-tunable width is promising as a device of a single element, and its structure and reflection characteristics will be described.

FIG. 6 is a schematic diagram for explaining the diffraction grating structure of the SSG-DBR. FIG. 6(a) shows the cross-sectional structure of an AXEL 400 by the SSG-DBR laser, and includes a rear DBR region 60a, an active region 70, a front DBR region 60b, and an SOA region 80 that are integrated along the optical axis direction. The rear DBR region 60a has a diffraction grating 61a, and the front DBR region 60b has a diffraction grating 61b. The structure of each of the diffraction gratings 61a and 61b differs from the normal DBR in FIG. 4 That is, the diffraction gratings 61a and 61b have a structure in which the diffraction grating period continuously and periodically changes from Λₐ to Λ_{b}.

FIG. 6(b) is a diagram showing the diffraction grating period in the SSG-DBR laser. The horizontal axis represents the positions of the diffraction gratings in the length direction thereof (waveguide direction), and the vertical axis represents the diffraction grating period. It should be noted that the period here is the pitch of the repeating structure of the diffraction gratings and has the dimension of length. The diffraction grating period of the SSG-DBR laser repeatedly changes between the maximum period Λₐ and the minimum period Λ_{b}, and the period of the change is Λₛ. As will be described later, a plurality of reflection peaks are generated in the SSG-DBR, and the number of reflection peaks and the wavelength interval between the reflection peaks can be designed by adjusting these parameters Λₐ, Λ_{b}, and Λₛ (NPL 5). In the reflection characteristics of the SSG-DBR, the reflection peak wavelength λ₀ at the center is determined by the following equation using the average value Λ₀ of diffraction grating periods that continuously change between the above-mentioned periods Λₐ to Λ_{b}.

Λ₀=2×n_{eq}×A₀ Equation (2)

Here, n_{eq} represents the equivalent refractive index of the DBR regions. In a normal SSG-DBR laser, the average value of the diffraction grating periods of the front DBR region and the rear DBR region is designed to be the same. Each diffraction grating of the SSG-DBR is set so that the position (wavelength) of the reflection peak located at the center among the plurality of reflection peaks coincides between the two DBR regions in a state where no current flows in the two DBR regions.

FIG. 7 is a diagram for explaining the behavior of a reflection peak with respect to the injection current in the SSG-DBR. FIG. 7(a) shows the reflective index of the two DBR regions of the SSG-DBR and the total reflective index, in a state where a DBR injection current is zero. In the state where the DBR injection current is 0 in the SSG-DBR laser, the two front and rear DBR regions have the same number (5) of reflection peaks. These reflection peaks are arranged at equal intervals, and the interval between the wavelength peaks is slightly different between the front DBR region and the rear DBR region. That is, the reflection peak interval Δλ_{front} of the front DBR region is designed to be slightly larger than the reflection peak interval Δλᵣₑₐᵣ of the rear DBR. By such arrangement of reflection peaks obtained by the design of the diffraction gratings, only one wavelength at which the reflection peaks of the two DBR regions coincide with each other in the wavelength-tunable band is always present due to the effect of the vernier. Laser oscillation occurs at a wavelength at which the reflection peaks of the two DBR regions coincide with each other.

Specifically, in the state where Iᵣₑₐᵣ=0 and I_{front}=0, in FIG. 7(a), the center peak wavelength 71 of the rear DBR region and the center peak wavelength 73 of the rear DBR region coincide with each other. In this state, the total reflection spectrum by the two DBR peaks at a center wavelength 75a, and actual resonance occurs only at one reflection peak of the center wavelength 75a. In a state where there is no injection current to the two DBR regions, the SSG-DBR laser oscillates at the wavelength of the resonant reflection peak.

FIG. 7(b) is a diagram for explaining a state in which the DBR injection current is adjusted and the oscillation mode is hopped to another reflection peak. Here, the relation of reflection spectra when the current to the front DBR region 61b is maintained at 0 and the current to the rear DBR region 61a is increased from 0 is shown. By the carrier plasma effect, all of the plurality of reflection spectra of the rear DBR region are shifted to the short wavelength side. In this state, the reflection peak wavelengths of the two DBR regions coincide with each other as peaks 72 and 74 shift to the short wavelength side from the center of the wavelength-tunable band by one, and thereby the oscillation wavelength is hopped to a peak 75b on the short wavelength side. Even in this state, only one reflection peak is consistent between the two front and rear DBR regions, and the SSG-DBR laser can obtain stable oscillation at a single wavelength.

In the DBR laser using the above-mentioned vernier effect, only one mode of resonance is required in the two front and rear DBR regions under any current condition, and the oscillation wavelength can be selectively controlled. Further, by simultaneously changing the injection currents to the two front and rear DBR regions from the state shown in FIG. 7(b), the oscillation wavelength shift by one reflection peak (equivalent to Bragg wavelength shift) is possible, similarly to the DBR laser of the single reflection peak shown in FIG. 5. The oscillation wavelength can be finely adjusted by the current injection into the DBR region. By combining oscillation mode selection by Bragg wavelength shift and the vernier effect, a plurality of discrete reflection peaks can be used for quasi-continuous wavelength control without wavelength gaps.

### CITATION LIST

### Patent Literature

[PTL 1] Japanese Patent Application Laid-open No. 2019212888

### Non Patent Literature

[NPL 1] W Kobayashi et al., “Novel approach for chirp and output power compensation applied to a 40-Gbit/s EADFB laser integrated with a short SOA,” Opt. Express, Vol. 23, No. 7, pp. 9533-9542, April 2015
[NPL 2] Y. Tohmori, Y. Suematsu, H. Tsushima, and S. Arai, “Wavelength tuning of GaInAsP/InP integrated laser with butt-jointed built-in distributed Brag reflector,” 1993, Electron. Lett., vol. 19, pp. 656-6583
[NPL 3] Y. Tohmori, Y. Yoshikuni, T. Tamamura, H. Ishii, Y. Kondo, and M. Yamamoto, “Broad-range wavelength tuning in DBR lasers with superstructure grating (SSG),” February 1999, IEEE Photon. Technol. Lett., vol. 5, No. 2, pp. 126-129
[NPL 4] B. Mason, G. A. Fish, S. P. DenBaars and L. A. Coldren, “Widely tunable sampled grating DBR laser with integrated electroabsorption modulator,” June 1999, IEEE Photonics Technology Letters, vol. 11, No. 6, pp. 638-640
[NPL 5] H. Ishii, H. Tanobe, F. Kano, Y. Tohmori, Y. Kondo, and Y. Yoshikuni, “Quasicontinuous wavelength tuning super-structure-grating (SSG) DBR lasers,” March 1996, IEEE J. Quantum Electron., vol. 32, No. 3

### SUMMARY OF INVENTION

### Technical Problem

A device in which a DBR laser having a wavelength-tunable function, an EA modulator, and an SOA are integrated (hereinafter referred to as a wavelength-tunable AXEL) has a problem that fluctuations in optical output cannot be avoided when a wavelength is changed. There are two main factors that cause the optical output to fluctuate in the wavelength-tunable Axel. One factor of the optical output fluctuation is an optical loss occurring in an EA modulator.

FIG. 8 is a conceptual diagram for explaining the modulation operation principle of an EA modulator. FIG. 8 shows two modulation states of an EA modulator, wherein the horizontal axis represents the wavelength and the vertical axis represents the absorption coefficient of the light transmitted through the modulator. The diagram shows an absorption curve 83 when a voltage is applied to the EA modulator (electric field ON), and an absorption curve 82 when a voltage is not applied (voltage OFF). FIG. 8 also schematically shows a case in which a wavelength group 81 of λ₀ to λ₃ is the wavelength of the light incident from each DBR laser onto the EA modulator, and the oscillation wavelength is set at any of λ₀ to λ₃ in the DBR laser.

As shown by the absorption curve 83 in FIG. 8 when the electric field is ON, by applying an electric field to the EA modulator, the absorption end of the absorption curve caused by the quantum well structure of the EA modulator shifts to the longer wavelength side, and the loss due to light absorption in the EA modulator increases and extinction occurs. By extinguishing the EA modulator, optical modulation corresponding to voltage application to the EA modulator can be realized. In an actual EA modulator, even when no electric field is applied (OFF), optical loss occurs as shown by the absorption curve 82, and the loss increases as the wavelengths of the oscillation wavelength group 81 become short because the absorption edge of the absorption curve 82 touches the shorter wavelengths.

When the oscillation wavelength is changed to λ₀ to λ₁ that the absorption curve 82 touches at the time of electric field OFF, an applied voltage V_{dc} and a signal amplitude voltage Vₚₚ to the EA modulator shown in FIG. 2 need to be adjusted to optimum conditions, respectively. However, even if these voltages are adjusted, it is inevitable in principle that the optical output at the time of modulation decreases toward the shorter wavelength side. Therefore, in the wavelength-tunable AXEL, the shorter the oscillation wavelength, the lower the optical output during modulation. That is, when the optical output of each wavelength is represented by a wavelength, the optical output establishes a relationship of λ₀<λ₁ <λ₂<λ₃, and the optical output decreases as the wavelength becomes short. The shorter the wavelength, the lower the optical output, so the output characteristic of the EA modulator taking the wavelength on the horizontal axis becomes the characteristic of the left-downward slope as a whole.

Another factor of the optical output fluctuation is the fluctuation in the optical output in the wavelength-tunable DBR laser before light enters the EA modulator. In the wavelength-tunable AXEL, fluctuations in the optical output also occur in the wavelength-tunable DBR laser before light enters the EA modulator, affecting the final optical output level of the wavelength-tunable AXEL. The optical output fluctuation of the wavelength-tunable DBR laser is due to a change in carrier density in the DBR region by carrier injection when performing a wavelength-tunable operation. As described above, the carrier plasma effect is a phenomenon in which the refractive index is reduced as a result of an increase in carrier density in the DBR region by current injection. In order to greatly vary the refractive index of the DBR region, the carrier density needs to be varied significantly. On the other hand, as the carrier density increases, optical absorption by free carriers increases inside the DBR region, which in turn increases the optical loss in the DBR region and decreases the output optical intensity.

FIG. 9 is a diagram for schematically explaining a fluctuation in the optical output intensity of the wavelength-tunable AXEL caused by carrier injection. FIG. 9 (a) shows a wavelength fluctuation of a reflective index and an optical output for a typical DBR laser having a single reflection peak. By applying a current to the two front and rear DBR regions, a reflection peak 90 of the DBR is shifted to the short wavelength side by the carrier plasma effect. The oscillation wavelength shifts to the short wavelength side with the shift of the reflection peak 90, but the optical loss in the DBR regions also increases. As a result, as shown in the lower diagram of (a), the more the oscillation wavelength shifts to shorter wavelengths with current injection, the more the optical output decreases to the left.

FIG. 9(b) shows a wavelength fluctuation of a reflective index and an optical output in the case of a wavelength-tunable laser consisting of a special DBR structure with a plurality of reflection peaks, such as an SSG-DBR laser. The upper diagram of FIG. 9(b) shows reflective indexes of two DBR regions of the SSG-DBR, as in FIG. 7, wherein no current is applied to any of the DBR regions. Here, it is assumed that the optical gain of the active layer is uniform regardless of the wavelength and that all reflection peaks have a uniform reflective index. In FIG. 9(b), the wavelength of the reflection peak 90 located just at the center of the wavelength-tunable band out of the seven reflection peaks coincides in the two front and rear DBR regions, and the oscillation occurs at this wavelength. Since the currents of the front DBR region and the rear DBR region are independently controlled, the entire reflection peak can be shifted to the short wavelength side for each DBR region. By finely adjusting the two DBR currents, one of the plurality of reflection peaks is selectively made consistent in the two DBR regions, and the oscillation wavelength can be changed.

Also in the SSG-DBR laser, the carrier densities in the DBR regions are increased by the adjustment of the DBR currents, and the loss is increased, so that the optical output is reduced. In the DBR laser using a plurality of reflection peaks, the control of the oscillation wavelength by the DBR currents is slightly complicated, but as schematically shown in the lower diagram of FIG. 9(b), the optical output fluctuates with the wavelength while fine level fluctuations in the shape of a saw tooth is repeated. The optical output characteristics of the SSG-DBR laser depend on the amount of current injected into the two front and rear DBR regions, and the optical output decreases to the left toward the shorter wavelength side within a wavelength region where the same reflection peak corresponding to one sawtooth is used.

Normally, the SSG-DBR laser is designed so that the wavelengths of the reflection peaks at the center among the plurality of reflection peaks in the wavelength-tunable band coincide with each other in a state where no current is injected in the two front and rear DBR regions. Therefore, the state in which no current is injected in the DBR region becomes the state in which the light intensity is the largest. The amount of current injected into the DBR regions increases as the wavelength for matching reflection peaks between the two DBR regions separates from the reflection peak (the state where DBR current is 0) at the center of the plurality of reflection peaks. Therefore, the optical output tends to decrease as the DBR current increases. As a result, as shown in the lower diagram of FIG. 9(b), the optical output is generally lowest when the oscillation wavelength is set to the shortest wavelength side.

Due to the two factors described above, the optical output at the time of modulation in the wavelength-tunable AXEL varies with each wavelength, and particularly, the decrease in the optical output becomes significant on the short wavelength side. The present invention has been made in view of the foregoing problems, and an object thereof is to provide a wavelength-tunable optical transmitter in which wavelength dependency of optical output is improved.

### Solution to Problem

One aspect of the present invention is a wavelength-tunable optical transmitter in which a wavelength-tunable light source and a field-absorption optical modulator that is optically connected to a forward DBR region are integrated along an optical axis direction, the wavelength-tunable light source including a rear DBR region with a first diffraction grating and a reflection characteristic consisting of a plurality of reflection peaks, an active region producing an optical gain, and the front DBR region with a second diffraction grating and a reflection characteristic consisting of a plurality of reflection peaks, wherein a wavelength interval of the reflection peaks of the front DBR region set to be greater than a wavelength interval of the reflection peaks in the rear DBR region, and an average period Λ_{0_front} of the first diffraction grating is set to be greater than an average period Λ_{0_rear} of the second diffraction grating.

The first diffraction grating and the second diffraction grating can be configured such that a wavelength of a reflection peak of a shortest wavelength among the plurality of reflection peaks of the rear DBR region coincides with a wavelength of a reflection peak of a shortest wavelength among the plurality of reflection peaks of the front DBR region when a first injection current to the rear DBR region and a second injection current to the front DBR region are zero.

### Advantageous Effects of Invention

According to the present invention, a wavelength-tunable optical transmitter with improved wavelength dependency of optical output can be provided.

### BRIEF DESCRIPTION OF DRAWINGS

FIG. 1 is a diagram showing a schematic configuration of a general EADFB laser.

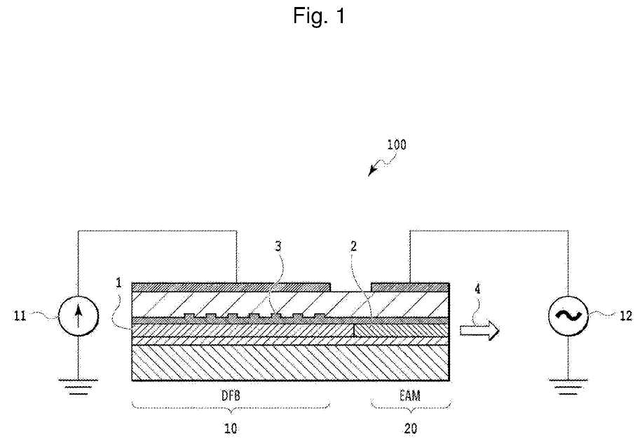

FIG. 2 is a diagram schematically showing an extinction curve and an intensity modulation principle of the EADFB laser.

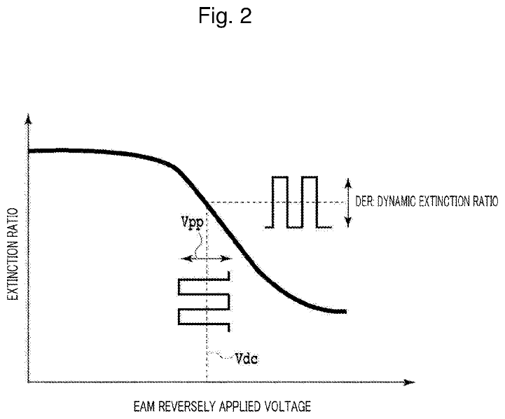

FIG. 3 is a diagram showing a configuration of an AXEL with SOAs integrated in the EADFB laser.

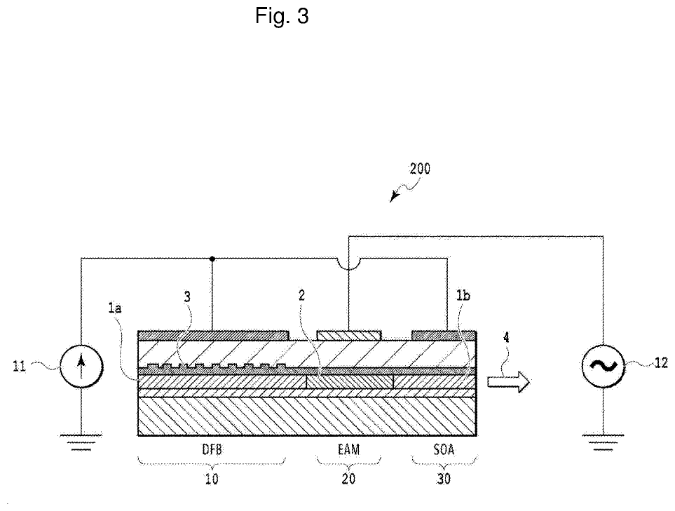

FIG. 4 is a diagram showing a schematic cross-sectional structure of a general DBR laser.

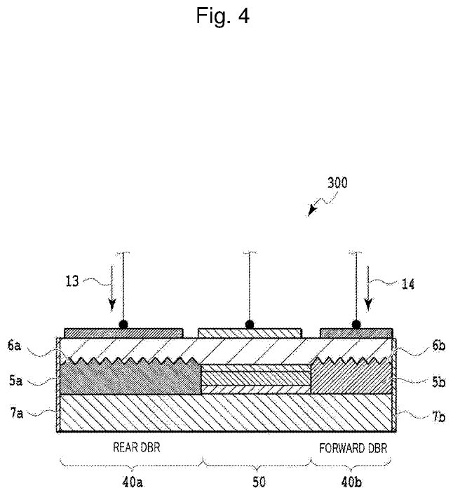

FIG. 5 is a diagram for explaining control of a reflection spectrum and an oscillation wavelength of a DBR region.

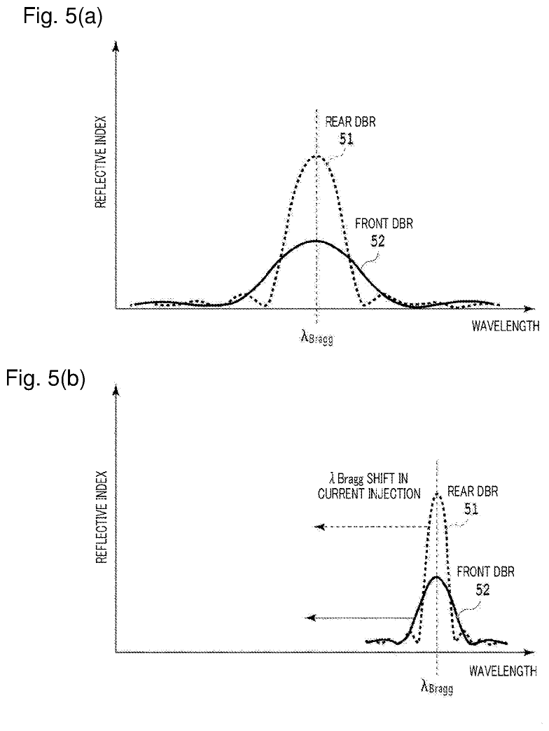

FIG. 6 is a schematic diagram for explaining a diffraction grating structure of an SSG-DBR.

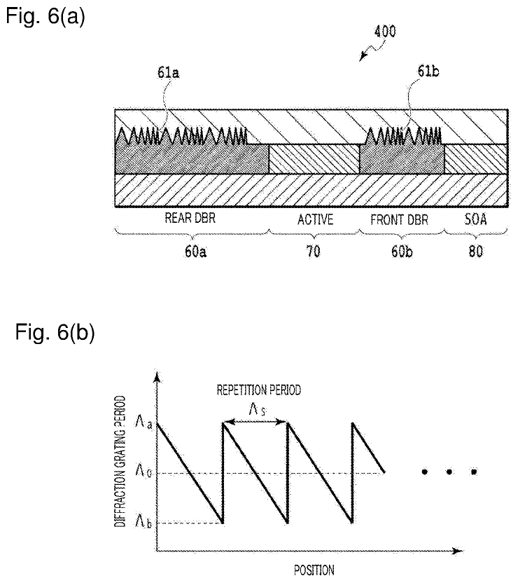

FIG. 7 is a diagram for explaining a behavior of an injected current-reflection peak of an SSG-DBR laser.

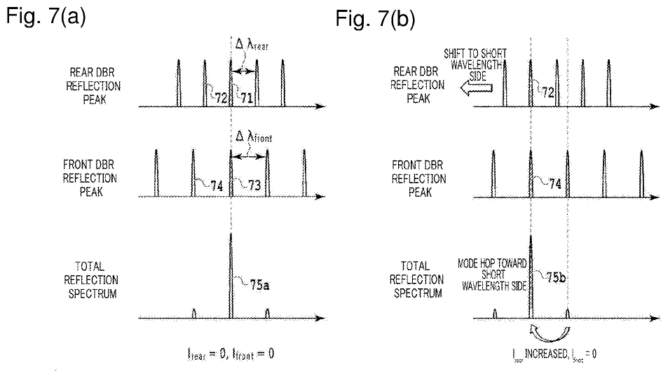

FIG. 8 is a conceptual diagram for explaining a modulation operation principle of an EA modulator.

FIG. 9 is a diagram for explaining optical output fluctuations of a wavelength-tunable AXEL associated with carrier injection.

FIG. 10 is an explanatory diagram of an SSG-DBR laser operation of the wavelength-tunable optical transmitter of the present disclosure.

FIG. 11 is a diagram showing a cross-sectional configuration of a wavelength-tunable optical transmitter of Example 1.

FIG. 12 is a diagram showing an optical output intensity of a sample B by a diffraction grating of the prior art.

FIG. 13 is a diagram showing an optical output intensity of a sample A by a diffraction grating of Example 1.

FIG. 14 is a diagram showing an optical output intensity of a wavelength-tunable optical transmitter of Example 2.

### DESCRIPTION OF EMBODIMENTS

A wavelength-tunable optical transmitter of the present disclosure includes at least a transmission function of integrating a DBR laser and an EA modulator, modulating light generated by the DBR laser by an information signal in the EA modulator, and transmitting the modulated optical signal. In the DBR laser of the wavelength-tunable transmitter of the present disclosure, a rear DBR region, an active region, and a front DBR region are integrated on a semiconductor substrate in this order along an optical axis direction. The DBR laser is an SSG-DBR having a plurality of reflection peaks in both the rear DBR region and the front DBR region. A diffraction grating structure is set so that an oscillation mode using a reflection peak on the shortest wavelength side among a plurality of reflection peaks corresponding to the wavelength-tunable band is easily oscillated the most in a state where a current to the two DBR regions of the SSG-DBR is 0.

In the wavelength-tunable transmitter of the present disclosure, a DBR laser is configured such that an average period value of a diffraction grating of the front DBR is larger than an average period value of a diffraction grating of the rear DBR. The diffraction grating is configured so that the wavelengths of the reflection peaks on the shortest wavelength side among the plurality of reflection peaks coincide with each other between the two DBR regions in a state where no current is supplied to the two front and rear DBR regions. In the SSG-DBR laser of the prior art, the average period value of the diffraction grating in the rear DBR region and the average period value of the diffraction grating in the front DBR region are designed to be the same. Furthermore, in a state in which no current flows through the two DBR regions, the wavelength of the central reflection peak among the plurality of reflection peaks in the rear DBR region coincides with the wavelength of the central reflection peak among the plurality of reflection peaks in the front DBR region. The configuration and operation of the SSG-DBR laser in the wavelength-tunable optical transmitter of the present disclosure will be described below with reference to the configuration of the diffraction grating of the SSG-DBR laser of the prior art.

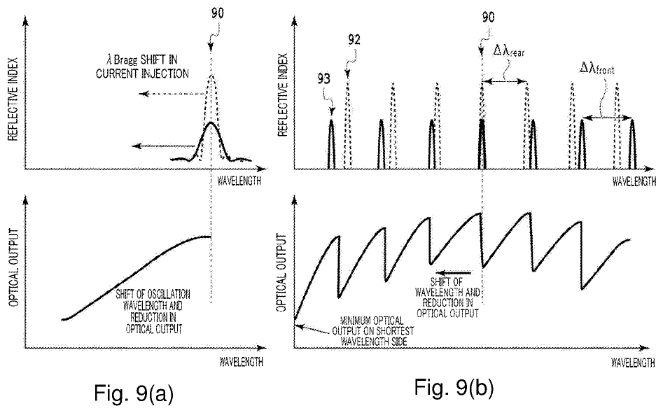

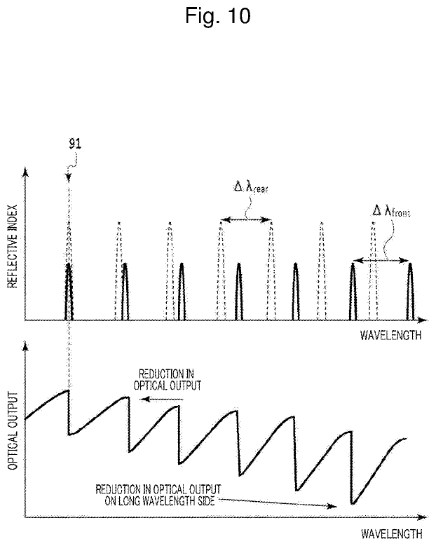

FIG. 10 is a diagram for explaining an SSG-DBR laser operation of the wavelength-tunable optical transmitter of the present disclosure. The SSG-DBR laser of the wavelength-tunable optical transmitter of the present disclosure is configured to oscillate at a reflection peak wavelength on the short wavelength side among a plurality of reflection peaks in a state where no DBR current flows. In this state, the optical loss due to the free carriers is minimized. The upper diagram of FIG. 10 shows reflection characteristics of two DBR regions in a state where no DBR current flows. The lower diagram of FIG. 10 shows the wavelength dependency of the optical output of the SSG-DBR laser of the wavelength-tunable optical transmitter of the present disclosure. The two diagrams of FIG. 10 correspond to the two diagrams of FIG. 9(b) in terms of the SSG-DBR laser of the prior art, and the description will be made with comparison with the configuration of the prior art.

First, the wavelength dependency of the optical output of the SSG-DBR laser will be outlined with reference to the lower diagram of FIG. 10. In the optical output of the SSG-DBR laser of the wavelength-tunable optical transmitter of the present disclosure, fine light intensity fluctuations of saw teeth-like repetition corresponding to the number of reflection peaks in the DBR regions can be seen. However, the overall wavelength-tunable bandwidth has a right-downward sloping characteristic, and the optical output tends to be higher at shorter wavelengths and gradually decreases toward the longer wavelengths. Among the repeated optical output fluctuations, the left-downward optical output fluctuation within one saw tooth corresponds to one of the plurality of reflection peaks in each of the two DBR regions. Thus, as in the case of the prior art in FIG. 9(b), oscillations occur using the same reflection peak within the wavelength range corresponding to one saw tooth.

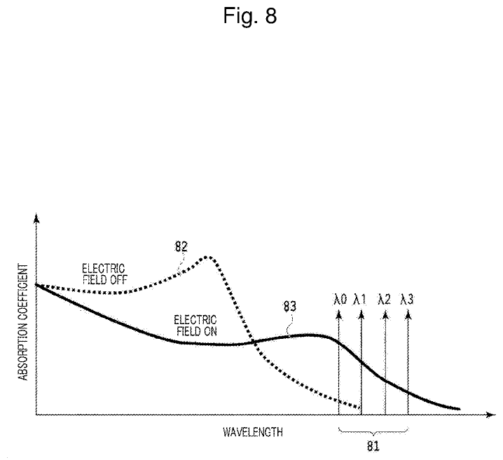

The wavelength dependency of the optical output of the SSG-DBR laser of the wavelength-tunable optical transmitter of the present disclosure represents a change in the optical output dependent on the current in the front DBR region and the current in the rear DBR region. The optical output characteristic of a right-downward shift across the wavelength-tunable band in FIG. 10 is achieved by setting the structure of each diffraction grating to oscillate in the shorter wavelength side oscillation mode with as little as possible of the two DBR currents, as described below. By setting the diffraction grating structure specific to the present invention, the SSG-DBR laser of the wavelength-tunable optical transmitter of the present disclosure can obtain a higher optical output on the short wavelength side than on the long wavelength side. On the other hand, the EA modulator tends to have greater optical loss on the shorter wavelength side, as described in FIG. 8, and has an overall left-downward sloping characteristic. The “right-downward” optical output characteristic of the SSG-DBR laser of the present disclosure and the “left-downward” optical output characteristic of the EA modulator are offset, and the optical output of the wavelength-tunable optical transmitter of the present disclosure provides a generally flat optical output characteristic over the entire wavelength range. Next, a more specific design of the diffraction grating in the SSG-DBR laser of the present disclosure will be described.

In determining the reflection characteristics of the SSG-DBR, the number of reflection peaks and the wavelength interval of the reflection peaks can be designed arbitrarily (NPL 5). In the SSG-DBR laser, the wider the wavelength interval of the reflection peaks or the larger the number of the reflection peaks is, the wider the wavelength range can be controlled. However, when the wavelength interval of the reflection peaks is widened, it is difficult to control the oscillation wavelength to the wavelength between the reflection peaks, and a wavelength gap which cannot be controlled in wavelength occurs between the reflection peaks. Further, if the number of reflection peaks is increased, the reflective index of one reflection peak decreases, and it becomes difficult to maintain laser oscillation. In order to widen the wavelength-tunable range, there are limits to increase in the number of reflection peaks and increase in the wavelength interval of reflection peaks in order to obtain pseudo continuous wavelength-tunable characteristics and stable laser oscillation.

Considering the characteristics of the SSG-DRB laser, it is necessary to set the number N of realistic reflection peaks to 5 to 11 in the wavelength-tunable band assumed in each band. The optimum value of the wavelength interval of the reflection peak varies depending on the oscillation wavelength band, and at a C band wavelength band (1530 to 1565 nm) or an L band wavelength band (1565 to 1625 nm), the wavelength interval of adjacent reflection peaks in the two DBR regions (wavelength difference) is set to 4 to 9 nm, respectively.

On the other hand, in an 0 band wavelength band (1260 to 1360 nm), in principle the refractive index change amount is smaller and the Bragg wavelength shift amount is smaller as compared with the C band. For this reason, it is necessary to set the wavelength interval between adjacent reflection peaks in the two DBR regions to 3 to 6 nm. When matching the peak wavelength of the shortest wavelength among the plurality of reflection peaks that the two DBR regions each have, the number of reflection peaks and the wavelength interval condition of the reflection peaks in the SSG-DBR described above must be considered.

Referring again to FIG. 10, a specific configuration of the diffraction grating of the SSG-DBR laser in the wavelength-tunable optical transmitter of the present disclosure will be described. FIG. 10 shows an example of reflection peak setting in the SSG-DBR laser of the present disclosure. As an example of the general structure of the C-band wavelength band, the number of reflection peaks N is 7 in the 1.55 μm wavelength band, the reflection peak interval in the front DBR region is Δλ_{front}=8.6 nm, and the reflection peak interval in the rear DBR region is Δλᵣₑₐᵣ=7.7 nm. In FIG. 10, the reflection characteristics of the front DBR region and the reflection characteristics of the rear DBR region are shown by solid lines and broken lines respectively, in a state where no current flows through the two DBR regions. What is characteristic of the SSG-DBR laser of the present disclosure is that the wavelength at which the reflection peaks coincide between the two DBR regions with no current flowing in the DBR regions is the reflection peak on the shortest wavelength side of the plurality of reflection peaks. In other words, the diffraction grating is set so that the reflection peak wavelength 91 on the shortest wavelength side among the plurality of reflection peaks in the front DBR region coincides with the reflection peak wavelength 91 on the shortest wavelength side among the plurality of reflection peaks in the rear DBR region.

It is necessary that the wavelength range including the plurality of reflection peaks in the two DBR regions includes at least the desired wavelength-tunable range in the wavelength-tunable transmitter in a state where no current flows in the DBR regions. This is because the reflection peak on the longest wavelength side of the plurality of reflection peaks shifts only to the short wavelength side even if a current is made to flow in the DBR regions, and therefore the oscillation wavelength cannot be adjusted to the longer wavelength side than the reflection peak on the longest wavelength side.

Specifically, the average value of the diffraction grating period is adjusted so that the wavelengths of reflection peaks on the shortest wavelength side coincide with each other with respect to the two DBR regions. In the configuration example shown in FIG. 10, the diffraction grating structure is set so that the average value Λ_{0_front} of the diffraction grating periods of the front DBR region is 0.23% larger than the average value Λ_{0_rear} of the diffraction grating periods of the rear DBR region. Thus, the entire reflection characteristics of the front DBR region are gradually shifted to the longer wavelength side in relation to the rear DBR region, and a wider reflection peak arrangement is obtained. The period of the diffraction grating represents the physical length (pitch) of the repetition of the repeating structure of the formed bumps and dips on the top surface of the active layer, which has a dimension of length. Note that the normal term “period” differs from the one having the dimension of time.

Here, the reflection characteristics of the SSG-VDBR laser of the prior art shown in FIG. 9 and the reflection characteristics of the SSG-VDBR laser in the wavelength-tunable optical transmitter of the present disclosure shown in FIG. 10 will be compared with each other. In the SSG-BLD DBR laser of the prior art, the average values of the diffraction grating periods of the two DBR regions are designed to be the same. For this reason, as shown in FIG. 9(b), the wavelengths of the reflection peaks located at the center among the plurality of reflection peaks corresponding to the wavelength-tunable band coincide with each other. When a wavelength 92 of a reflection peak on the shortest wavelength side of the rear DBR region is compared with a wavelength 93 of a reflection peak on the shortest wavelength side of the front DBR region in a state where no current flows to the two DBR regions, a wavelength difference is approximately 3.6 nm.

On the other hand, in the SSG-DBR laser in the wavelength-tunable optical transmitter of the present disclosure shown in FIG. 10, the wavelength of the reflection peak on the shortest wavelength side of the rear DBR region and the wavelength of the reflection peak on the shortest wavelength side of the front DBR region are made to coincide with each other. In this manner, in the two DBR regions, if the wavelengths of the reflection peaks on the shortest wavelength side among the plurality of reflection peaks coincide with each other, the mode on the shortest wavelength side oscillates in a state where no DBR current flows. Also, when the oscillation wavelength is finely adjusted by using the mode on the shortest wavelength side, the wavelength can be adjusted by a relatively smaller DBR current than the prior art. Therefore, in the oscillation mode on the shortest wavelength side, the reduction in the optical output due to the application of the DBR current for wavelength adjustment is greatly suppressed. This is in contrast to the configuration of the prior art illustrated in FIG. 9(b), which required the maximum DBR current when adjusting the wavelength toward the shortest wavelength.

Therefore, the wavelength-tunable optical transmitter of the present invention is a wavelength-tunable optical transmitter in which a wavelength-tunable light source and a field-absorption optical modulator that is optically connected to a forward DBR region are integrated along an optical axis direction, the wavelength-tunable light source including a rear DBR region with a first diffraction grating and a reflection characteristic consisting of a plurality of reflection peaks, an active region producing an optical gain, and the front DBR region with a second diffraction grating and a reflection characteristic consisting of a plurality of reflection peaks, wherein a wavelength interval of the reflection peaks of the front DBR region set to be greater than a wavelength interval of the reflection peaks in the rear DBR region, and an average period Λ_{0_front} of the first diffraction grating is set to be greater than an average period Λ_{0_rear} of the second diffraction grating.

The first diffraction grating and the second diffraction grating can be configured such that a wavelength of a reflection peak of a shortest wavelength among the plurality of reflection peaks of the rear DBR region coincides with a wavelength of a reflection peak of a shortest wavelength among the plurality of reflection peaks of the front DBR region when a first injection current to the rear DBR region and a second injection current to the front DBR region are zero.

In the SSG-DBR laser of the present disclosure, preferred configurations of the two diffraction grating structures for each target wavelength-tunable band are as follows. Suppose that the average periods of the diffraction gratings in the front and rear DBR regions are Λ_{0_front} and Λ_{0_rear} respectively. Using the two average periods, the average period difference Δλ₀ between the two gratings is defined as in the following equation.

$${ΔΛ}_{0} = \frac{{Λ}_{0 \_ front} - {Λ}_{0 \_ rear}}{{Λ}_{0 \_ front}} \times 100 \qquad Equation ( 3 )$$

Assuming that the number of reflection peaks corresponding to the target wavelength-tunable range is N, when the oscillation wavelength is in the 1.55 μm band (C band wavelength band, L band wavelength band), the diffraction grating periods of the front DBR region and the rear DBR region are preferably designed to satisfy the following equation.

$$\frac{2 \times {ΔΛ}_{0}}{N - 1} = 0.04 ∼ 0.09 \% \qquad Equation ( 4 )$$

Furthermore, when the oscillation wavelength is in the 1.3 μm band (O-band wavelength band), the change in refractive index due to the carrier-plasma effect is smaller than in the 1.5 μm band. Therefore, it is preferable to design the diffraction grating periods of the front DBR region and the rear DBR region so as to satisfy the following equation.

$$\frac{2 \times {ΔΛ}_{0}}{N - 1} = 0.03 ∼ 0.06 \% \qquad Equation ( 5 )$$

A specific example of the wavelength-tunable optical transmitter including the SSG-DBR laser will be described below with reference to a specific configuration and improvement in wavelength dependency of the optical output level.

### Example 1

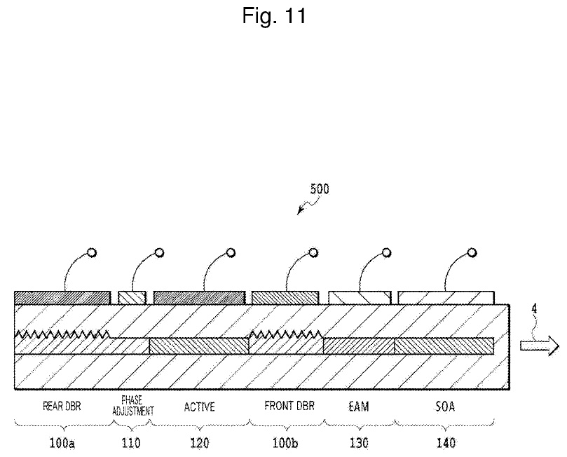

FIG. 11 is a diagram showing a cross-sectional configuration of a wavelength-tunable optical transmitter of Example 1. A wavelength-tunable optical transmitter 500 is a wavelength-tunable AXEL in which SOA is integrated in addition to an SSG-DBR laser and an EA modulator. In the SSG-DBR laser, an active region 120 having a length of 300 μm, a front DBR region 100b having a length of 200 μm, and a rear DBR region 100a having a length of 400 μm are configured in an optical axis direction. Further, an EA modulator 130 having a length of 200 μm and an SOA 140 having a length of 150 μm are integrated in front of the SSG-DBR laser along the optical axis direction, and the entire wavelength-tunable optical transmitter is configured as a monolithic integrated element. A phase adjustment region 110 is also provided between the active region 120 and the rear DBR region 100a. A modulated optical signal 4 is output from a substrate end surface on the SOA 140 side.

The manufacturing process of the wavelength-tunable optical transmitter 500 will now be described. An initial substrate in which a lower SCH (Separated Confinement Heterostructure) layer, an active layer of a multiple quantum well layer (MQW 1), and an upper SCH layer are sequentially grown on an n-InP substrate, is used for manufacturing the element. The multiple quantum well layer has an optical gain in an oscillation wavelength of 1.55 μm band. First, leaving a part that becomes the active region of the DBR laser and the SOA region, other active layers are selectively etched, and a multiple quantum well layer (MQW 2) for the EA modulator is grown by butt joint regrowth. Subsequently, leaving the active region of the DBR laser, the EA modulator region, and the SOA region, selective etching and butt joint regrowth are performed again to form a core layer of the passive waveguide. Next, an SSG-DBR diffraction grating that operates in the oscillation wavelength band of 1.55 μm and has an average period that satisfies the above equations (3) and (4) was formed in the two DBR regions. Thereafter, a p-InP clad layer was grown over the entire surface of the element by re-growth. In this example, the thickness of the cladding layer is set to 2.0 μm, and the electrode region is designed so that the light field is not applied.

After the cladding layer was grown, the mesa structure was formed by etching to form a ridge waveguide structure. Thereafter, a p-side electrode was formed on the upper surface of the semiconductor substrate. Thereafter, the InP substrate is polished to approximately 150 μm, and an electrode is formed on the rear surface of the substrate, completing the process on the semiconductor wafer. In the wavelength-tunable optical transmitter of the present example, the two DBR regions and the passive waveguide region have the same core layer formed by butt-joint growth, and the only difference in layer structure between these regions is the presence or absence of the diffraction grating. The active region and the SOA region also have a multi-quantum well layer of the same structure and are grown collectively. Thus, despite the structure in which a plurality of regions are integrated, the number of regrowth cycles can be reduced, and low-cost manufacturing is made possible.

Here, the structure of the diffraction gratings (SSG) formed in the two DBR regions 100a and 100b of the wavelength-tunable optical transmitter of Example 1 will be described. As described in FIG. 10, in the SSG-DBR laser of Example 1, the two DBR regions 100a and 100b have a plurality of reflection peaks, respectively, and the reflection peak intervals are slightly different between the two DBR regions. By the vernier effect, one peak among the plurality of reflection peaks can be selected in each of the two DBR regions to control the oscillation wavelength.

The two DBR regions 100a and 100b each have seven reflection peaks (N=7). The reflection peak intervals in the front DBR region and the rear DBR region are set to be Δλ_{front}=8.6 nm and Δλᵣₑₐᵣ=7.7 nm, respectively, and the reflection peak intervals in the front DBR region are designed to be slightly larger than the reflection peak intervals in the rear DBR region. In addition, the average period Λ_{0_front} in the diffraction grating in the front DBR region is designed to be slightly greater than the average period Λ_{0_rear} in the diffraction grating in the rear DBR region. From the values of the reflection peak intervals Δλ^{front} and Δλ^{rear} in the front DBR region and the rear DBR region and the number of reflection peaks N=7, the average periods Λ_{0_front} and Λ_{0_rear} of the respective diffraction gratings in the front DBR region and the rear DBR region are determined to satisfy the equation (4). As shown in the equation (4) for the 1.55 μm band, Λ_{0_front} is designed to be 0.174% greater than Λ_{0_rear} (ΔΛ₀=0.174).

By setting the diffraction grating structure as described above, the wavelengths of the reflection peaks of the shortest wavelength out of the plurality of reflection peaks of the two DBR regions coincide with each other and are brought into a resonant state in a state where no DBR current is injected into any of the two DBR regions.

A wavelength-tunable AXEL in which SSG-DBR lasers having the above-mentioned specific diffraction gratings are integrated was manufactured and evaluated. The element of the structure of the present example is taken as a sample A. In the present example, in order to confirm the improvement effect of the optical output characteristics by the SSG-DBR lasers having a specific diffraction grating, a wavelength-tunable AXEL having the same diffraction grating structure as that of the prior art was manufactured. In other words, devices having the same average value of diffraction grating periods in two DBRs were also manufactured and the same evaluation was performed. The element according to the configuration of the prior art is taken as a sample B. The samples A and B have the same structure except for the diffraction grating structure, and were fabricated using the same fabrication process.

The modulation characteristics of each oscillation wavelength were evaluated in each of the fabricated devices. The entire wavelength-tunable range was divided into channels at 100 GHz intervals, and the modulation characteristics were evaluated when the device was controlled to the corresponding wavelength of each channel. As for the SSG-DBR laser of each element, a current of 90 mA was injected into the active region and the SOA region, and the front DBR region, the rear DBR region, and the phase adjustment region were controlled, thereby adjusting the wavelength of each channel. The adjustment of the driving conditions in each channel was carried out under the condition that the oscillation wavelength was adjusted with accuracy of +/−0.01 nm with respect to the target wavelength, and that the optical output was maximized in a range satisfying SMSR >45 dB.

The EA modulator receives a modulation signal having a transmission rate of 10 Gbit/s, a signal format of NRZ, and a signal sequence of PRBS 2³¹−1, and has an amplitude voltage of 2.0 V at all times. For the DC bias voltage to the EA modulator, the EYE pattern waveform of the modulated optical signal was evaluated and adjusted to a value to maximize the dynamic extinction ratio. The absolute value of the voltage applied to the actual EA modulator tends to be smaller toward the short wavelength side channel and larger toward the long wavelength side. This tendency of the modulation signal is because the absorption curve of the EA modulator has a larger absorption toward the shorter wavelength side as described with reference to FIG. 8. The evaluated wavelength channels are 49 channels in both the sample A and the sample B.

The EYE pattern waveform was evaluated to obtain a relatively clear EYE aperture over all channels for both of the samples A and B, and a dynamic extinction ratio of 6 dB or more was confirmed over all channels. In order to confirm the effect of the SSG-DBR laser having the above-mentioned specific diffraction grating, the optical output intensities of all channels measured in the samples A and B were compared.

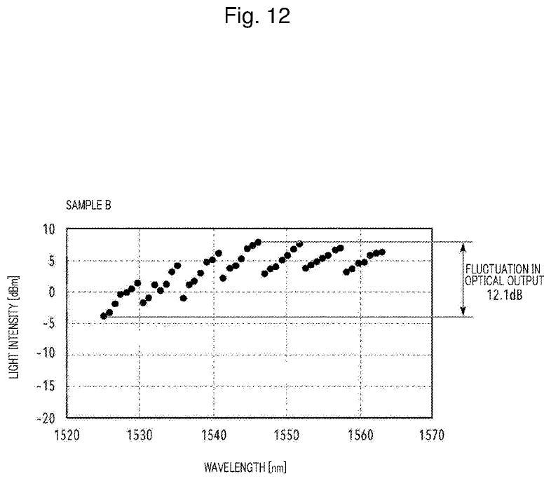

FIG. 12 is a diagram showing the optical output intensity of the sample B by the diffraction grating with the configuration of the prior art. Over the entire wavelength-tunable band, there are seven fluctuations in the optical output in the form of sawteeth. These fluctuations in the optical output indicate that the oscillation state is determined by one of the seven different reflection peaks in each of the two DBR regions. The point within one sawtooth range corresponds to the oscillation state set by different DBR currents using the same reflection peak. Within one sawtooth range, the characteristic of the leftward drop in which the optical output decreases as the DBR current increases. It is possible to confirm the tendency of the leftward decrease in which the optical output decreases toward the shorter wavelength side over the entire wavelength-tunable band. The leftward decrease tendency is derived from the wavelength dependency of the optical loss of the EA modulator as described with reference to FIG. 8. The leftward decrease of the optical output is a problem to be solved. A maximum optical output of 8.1 dBm was obtained in a channel approximately in the center of the wavelength-tunable range. On the other hand, the minimum optical output was obtained by the channel of the shortest wavelength, and the optical output thereof was approximately −4 dBm. Therefore, the optical output between channels has a fluctuation with a maximum width of 12.1 dB in the entire wavelength-tunable range. In this manner, when the wavelength-tunable AXEL is constituted by the SSG-DBR laser using the diffraction grating having the configuration of the prior art, a very large fluctuation in the optical output is caused depending on the wavelength.

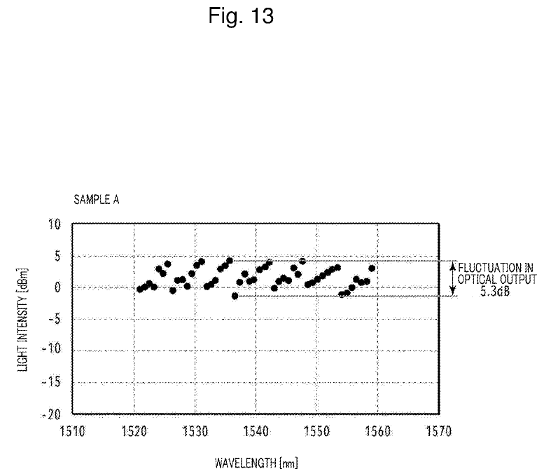

FIG. 13 is a diagram showing the optical output intensity of the sample A by the diffraction grating having the configuration of the present disclosure. In the sample A as well, it is possible to confirm seven fine optical output fluctuations representing optical fluctuations in the seven SSG modes. However, unlike the sample B of the prior art shown in FIG. 12, there is no significant decrease in the optical output on the short wavelength side, and a uniform optical output is obtained over the entire wavelength-tunable range. The maximum value of the optical output was 4.2 dB, which was slightly lower than that of the sample B according to the prior art, but the total optical output fluctuation width was 5.3 dB at maximum, which was reduced from 12.1 dB of the sample B according to the prior art by 7 dB. This is caused by an improvement in the reduction of the optical output on the short wavelength side. The optical loss in the EA modulator has the same tendency for both of the samples A and B because of the same configuration. The wavelength dependency of the optical loss in the EA modulator was compensated by designing the diffraction grating so that the optical output from the laser was maximized on the short wavelength side by adopting the SSG-DBR structure of the present disclosure. A uniform optical output was obtained in the entire wavelength-tunable optical transmitter.

### Example 2

The present example describes a wavelength-tunable optical transmitter in which the oscillation wavelength is set to 1.3 μm band and which corresponds to high-speed modulation of 25 Gbit/s class. Since the basic structure of the device of the present embodiment is the same as that of the device of Example 1 shown in FIG. 11, description thereof is omitted accordingly.

Compared with the operation in the 1.55 μm band of Example 1, the operation in the 1.3 μm band of the present example requires designing the reflection peak intervals of the two DBR regions to be smaller. This is because in the 1.3 μm band, the amount of change in refractive index and the amount of wavelength shift due to the carrier plasma effect are smaller than those in the 1.55 μm band. In the present example, the two DBR regions each have nine reflection peaks (N=9). The reflection peak intervals in the front DBR region and the rear DBR region are Δλ_{front}=4.0 nm and Δλᵣₑₐᵣ=3.5 nm, respectively, and the reflection peak intervals of the front DBR region are slightly greater than the reflection peak intervals of the rear DBR region. In addition, the average period Λ_{0_front} in the diffraction grating in the front DBR region is designed to be slightly greater than the average period Λ_{0_rear} in the diffraction grating in the rear DBR region. From the values of the reflection peak intervals ΔΛ_{front} and ΔΛᵣₑₐᵣ in the front DBR region and the rear DBR region and the number of reflection peaks N=9, the average periods Λ_{0_front} and Λ_{0_rear} of the respective diffraction gratings in the front DBR region and the rear DBR region are determined to satisfy the equation (5). Λ_{0_front} is designed to be 0.154% greater than Λ_{0_rear} (ΔΛ₀=0.154).

By setting the diffraction gratings to satisfy the equation (5) as described above, the reflection peaks of the shortest wavelength among the plurality of reflection peaks of the two DBR regions coincide with each other in the state where no DBR current is injected, resulting in a state of resonance. In the same manner as in Example 1, a wavelength-tunable AXEL in which SSG-DBR lasers are integrated was prepared and evaluated.

In each device manufactured in the same manner as in Example 1, the modulation characteristics for each oscillation wavelength were evaluated. The entire wavelength-tunable range was divided into channels at 100 GHz intervals, and the modulation characteristics were evaluated when the device was controlled to the corresponding wavelength of each channel. As for the SSG-DBR laser of each element, a current of 90 mA was injected into the active region and a current of 120 mA was injected into the SOA region, and the front DBR region, the rear DBR region, and the phase adjustment region were controlled independently, thereby adjusting the wavelength of each channel. The adjustment of the driving conditions in each channel was carried out under the condition that the wavelength was adjusted with accuracy of +/−0.01 nm with respect to the target wavelength, and that the optical output was maximized in a range satisfying SMSR >45 dB.

The EA modulator receives a modulation signal having a transmission rate of 25 Gbit/s, a signal format of NRZ, and a signal sequence of PRBS 2³¹−1, and has an amplitude voltage of 1.5 V at all times. For the DC bias voltage to the EA modulator, the EYE pattern waveform of the modulated optical signal was evaluated and adjusted to a voltage value to maximize the dynamic extinction ratio. The absolute value of the voltage applied to the actual EA modulator tends to be smaller toward the short wavelength side channel and larger toward the long wavelength side. As with Example 1, this is because the absorption curve of the EA modulator has a larger absorption toward the shorter wavelength side. The evaluated wavelength channels are 55 channels in both the sample A and the sample B. The Eye pattern waveform of each channel was evaluated to obtain a clear EYE aperture in all channels. It was confirmed that the dynamic extinction ratio was 5.5 dB or greater over the entire channels.

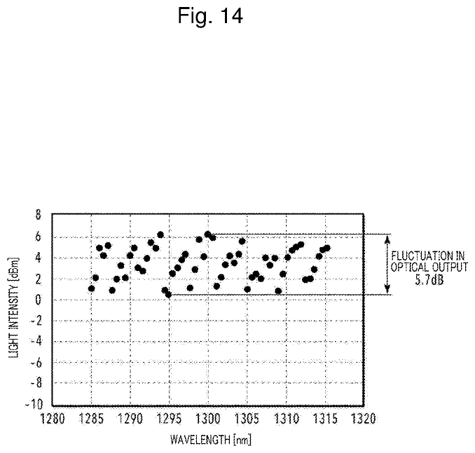

FIG. 14 is a diagram showing the optical output intensity of of a wavelength-tunable optical transmitter of Example 2. In the entire wavelength-tunable range, it is possible to confirm nine fine optical output fluctuations representing optical fluctuations in an SSG mode. However, unlike the sample B using the SSG-DBR laser of the prior art shown in FIG. 12, no significant decrease in the optical output on the short wavelength side is observed, and a uniform optical output is obtained over the entire wavelength-tunable range, as in Example 1. The wavelength of the channel where the maximum optical output was obtained was 1300 nm and the optical output at the time of modulation was 6.3 dBm. The channel having the minimum optical output had a wavelength of 1295 nm, and the optical output at the time of modulation was 0.6 dBm. The fluctuation width of the entire optical output was 5.7 dB at maximum, and compared with the fluctuation width of 12.1 dB in the configuration of the prior art shown in FIG. 11, the wavelength dependency of the optical output was greatly improved.

In each of the examples described above, the wavelength-tunable optical transmitter has been described assuming that SOAs are also integrated. However, a wavelength-tunable optical transmitter having a configuration in which only a wavelength-tunable DBR laser and an EA modulator are integrated without including SOA exhibits the same effect as in the examples, and the wavelength dependency of the final optical output from the EA modulator is improved.

As described in detail above, in the wavelength-tunable optical transmitter of the present disclosure, the diffraction grating of the SSG-DBR is set to a configuration different from that of the prior art so that oscillation occurs at the reflection peak of the shortest wavelength in the absence of a DBR current. Thus, a flat optical output characteristic in which the wavelength dependency of the final optical output is suppressed is realized.

### INDUSTRIAL APPLICABILITY

The present invention can be applied to a communication device in an optical communication system.

1. A wavelength-tunable optical transmitter in which a wavelength-tunable light source and a field-absorption optical modulator that is optically connected to a forward DBR region are integrated along an optical axis direction, the wavelength-tunable light source including a rear DBR region with a first diffraction grating and a reflection characteristic consisting of a plurality of reflection peaks,
an active region producing an optical gain, and
the front DBR region with a second diffraction grating and a reflection characteristic consisting of a plurality of reflection peaks, wherein
a wavelength interval of the reflection peaks of the front DBR region set to be greater than a wavelength interval of the reflection peaks in the rear DBR region, and
an average period A_{0_front} of the first diffraction grating is set to be greater than an average period Λ_{0_rear} of the second diffraction grating.

2. The wavelength-tunable optical transmitter according to claim 1, wherein the first diffraction grating and the second diffraction grating are configured such that a wavelength of a reflection peak of a shortest wavelength among the plurality of reflection peaks of the rear DBR region coincides with a wavelength of a reflection peak of a shortest wavelength among the plurality of reflection peaks of the front DBR region when a first injection current to the rear DBR region and a second injection current to the front DBR region are zero.

3. The wavelength-tunable optical transmitter according to claim 1, wherein an oscillation wavelength of the wavelength-tunable light source is changed by injecting a first injection current into the front DBR region and a second current into the rear DBR region.

4. The wavelength-tunable optical transmitter according to claim 1, wherein a variable range of an oscillation wavelength includes a C band or an L band,
the front DBR region and the rear DBR region have the same number of reflection peaks N, and
the _{first} diffraction grating and the second diffraction grating are configured so as to satisfy the following equations for an average period difference ΔΛ₀ between an average period Λ_{0_front} of the first diffraction grating and an average period Λ_{0_rear} of the second diffraction grating.
$${ΔΛ}_{0} = \frac{{Λ}_{0 \_ front} - {Λ}_{0 \_ rear}}{{Λ}_{0 \_ front}} \times 100 \\ and \\ 0.04 < \frac{2 \times {ΔΛ}_{0}}{N - 1} < 0.09 ( \% )$$

5. The wavelength-tunable optical transmitter according to claim 1, wherein a variable range of an oscillation wavelength includes an O band,
the _{front} DBR region and the rear DBR region have the same number of reflection peaks N, and
the _{fir'st} diffraction grating and the second diffraction grating are configured so as to satisfy the following equations for an average period difference ΔΛ₀ between an average period Λ₀ front of the first diffraction grating and an average period Λ_{0_rear} of the second diffraction grating.
$${ΔΛ}_{0} = \frac{{Λ}_{0 \_ front} - {Λ}_{0 \_ rear}}{{Λ}_{0 \_ front}} \times 100 \\ and \\ 0.03 < \frac{2 \times {ΔΛ}_{0}}{N - 1} < 0.06 ( \% )$$

6. The wavelength-tunable optical transmitter according to claim 1, wherein a semiconductor optical amplifier (SOA) is further integrated on an output side of the field-absorption optical modulator.

7. The wavelength-tunable optical transmitter according to claim 1, wherein a wavelength range of the plurality of reflection peaks of the first diffraction grating and a wavelength range of the plurality of reflection peaks of the second diffraction grating are included at least in a wavelength-tunable range by the wavelength-tunable light source.

8. The wavelength-tunable optical transmitter according to claim 2, wherein a semiconductor optical amplifier (SOA) is further integrated on an output side of the field-absorption optical modulator.

9. The wavelength-tunable optical transmitter according to claim 3, wherein a semiconductor optical amplifier (SOA) is further integrated on an output side of the field-absorption optical modulator.

10. The wavelength-tunable optical transmitter according to claim 4, wherein a semiconductor optical amplifier (SOA) is further integrated on an output side of the field-absorption optical modulator.

11. The wavelength-tunable optical transmitter according to claim 5, wherein a semiconductor optical amplifier (SOA) is further integrated on an output side of the field-absorption optical modulator.

12. The wavelength-tunable optical transmitter according to claim 2, wherein a wavelength range of the plurality of reflection peaks of the first diffraction grating and a wavelength range of the plurality of reflection peaks of the second diffraction grating are included at least in a wavelength-tunable range by the wavelength-tunable light source.

13. The wavelength-tunable optical transmitter according to claim 3, wherein a wavelength range of the plurality of reflection peaks of the first diffraction grating and a wavelength range of the plurality of reflection peaks of the second diffraction grating are included at least in a wavelength-tunable range by the wavelength-tunable light source.

14. The wavelength-tunable optical transmitter according to claim 4, wherein a wavelength range of the plurality of reflection peaks of the first diffraction grating and a wavelength range of the plurality of reflection peaks of the second diffraction grating are included at least in a wavelength-tunable range by the wavelength-tunable light source.

15. The wavelength-tunable optical transmitter according to claim 5, wherein a wavelength range of the plurality of reflection peaks of the first diffraction grating and a wavelength range of the plurality of reflection peaks of the second diffraction grating are included at least in a wavelength-tunable range by the wavelength-tunable light source.
